(19) United States
(12) Patent Application Publication
(10) Pub. No.: US 2015/0270300 A1
(43) Pub. Date: Sep. 24, 2015

(54) CMOS IMAGE SENSOR AND METHOD OF MANUFACTURING THE SAME

(71) Applicant: Man Lyun HA, Icheon-si (KR)

(72) Inventor: Man Lyun HA, Icheon-si (KR)

(73) Assignee: Dongbu HiTekCo., Ltd., Seoul (KR)

(21) Appl. No.: 14/455,736

(22) Filed: Aug. 8, 2014

(30) Foreign Application Priority Data
Mar. 20, 2014 (KR) 10-2014-0032439

(51) Int. Cl. H01L 27/146

(52) U.S. Cl. CPC H01L 27/14612; H01L 27/14689; H01L 27/1461

(57) ABSTRACT

A complementary metal-oxide-semiconductor (CMOS) image sensor includes a transfer gate formed on a substrate; a photo diode formed at or in a surface portion of the substrate on one side of the transfer gate, a floating diffusion region formed at or in a surface portion of the substrate on another side of the transfer gate, a first impurity region having a first conductive type formed at or in a surface portion of the substrate between the photo diode and the floating diffusion region, and a buried channel region having a second conductive type formed under the first impurity region.

### CROSS-REFERENCE TO RELATED APPLICATION

This application claims priority to Korean Patent Application No. 10-2014-0032439, filed on Mar. 20, 2014, and all the benefits accruing therefrom under 35 U.S.C. §119, the contents of which are incorporated by reference in their entirety.

### BACKGROUND

The present disclosure relates to an image sensor and a method of manufacturing the same. In more detail, the present disclosure relates to a complementary metal-oxide-semiconductor (CMOS) image sensor and a method of manufacturing the same.

In general, image sensors, as semiconductor devices converting optical images into electrical signals, may be classified as charge coupled devices (CCDs) on CMOS image sensors (CISs).

The CMOS image sensor may include a plurality of pixels, and each pixel may include a photo diode and one or more MOS transistors. The CMOS image sensor may form an image by sequentially detecting electrical signals from the pixels using a switching method.

The CMOS image sensor may be manufactured by forming photo diodes and transistors connected to the photo diodes on a semiconductor substrate, forming wiring layers functioning as signal lines connected to the transistors, and forming a color filter layer and micro lenses on or over the wiring layers.

Particularly, the CMOS image sensor may include a plurality of pixel regions arranged in a plurality of rows and a plurality of columns. A photo diode, a transfer gate, and a floating diffusion region may be formed in each pixel region. The photo diode may include a p-type surface region and an n-type storage region. Electrons (i.e., charge or charge carriers) generated by light incident to the photo diode may be stored in the n-type storage region. The charge or charge carriers may be transferred to the floating diffusion region via the transfer gate.

On the other hand, when charge or charge carriers are transferred from the photo diode to the floating diffusion region during an integration period, a small amount of the charge or charge carriers generated during an integration period may remain in the photo diode. The charge or charge carriers remaining in the photo diode may reduce the dynamic range of the CMOS image sensor and may lead to or cause easy saturation of the photo diode.

When the photo diode is saturated, charge leakage may occur to an adjacent pixel region, and cross-talk may thus occur. Additionally, when excessive charges overflow from the photo diode into adjacent pixel regions, a “blooming” phenomenon may occur.

In order to improve (e.g., reduce) the charge leakage, cross-talk and the “blooming” phenomenon due to overflow, a technique of arranging an anti-blooming transistor in a pixel region was suggested. However, in this case, an array architecture of the CMOS image sensor became more complex.

### SUMMARY

The present disclosure provides a CMOS image sensor including a photo diode with an increased dynamic range and a transfer transistor with an improved charge transfer efficiency and a method of manufacturing the same.

In accordance with one or more exemplary embodiments, a complementary metal-oxide-semiconductor (CMOS) image sensor may include a transfer gate on a substrate, a photo diode at or in a surface portion of the substrate on one side of the transfer gate, a floating diffusion region at or in a surface portion of the substrate on another side of the transfer gate, a first impurity region having a first conductive type at or in a surface portion of the substrate between the photo diode and the floating diffusion region, and a buried channel region having a second conductive type under the first impurity region.

The photo diode may include a second impurity region having the second conductive type at or in the surface portion of the substrate, a third impurity region having the second conductive type under the second impurity region, and a fourth impurity region having the first conductive type on the second impurity region.

The third impurity region may have a lower impurity concentration than the second impurity region.

The substrate may have the first conductive type.

The buried channel region between the photo diode and the floating diffusion region may have the same length as the first impurity region.

The buried channel region between the photo diode and the floating diffusion region may have a shorter length than the first impurity region.

The first impurity region between the photo diode and the floating diffusion region may have a shorter length than the buried channel region.

In accordance with one or more other exemplary embodiments, a method of manufacturing a complementary metal-oxide-semiconductor (CMOS) image sensor may include forming a first impurity region having a first conductive type at or in a surface portion of a substrate, forming a transfer gate on the first impurity region, forming a photo diode at or in a surface portion of the substrate on one side of the transfer gate, forming a buried channel region having a second conductive type under the first impurity region, and forming a floating diffusion region at or in a surface portion of the substrate on another side of the transfer gate.

Forming the photo diode may include forming a second impurity region having the second conductive type at or in a surface portion of the substrate, forming a third impurity region having the second conductive type under the second impurity region, and forming a fourth impurity region having the first conductive type on the second impurity region.

The buried channel region may be formed together (e.g., simultaneously) with the third impurity region.

The third impurity region may have a lower impurity concentration than the second impurity region.

The substrate may have the first conductive type.

Forming the buried channel region may include forming a photoresist pattern exposing the transfer gate, and performing an ion implantation process to form the buried channel region under the first impurity region.

The ion implantation process may be performed using an energy of about 400 KeV to about 1 MeV.

Forming the buried channel region may include forming a photoresist pattern partially exposing the transfer gate, and performing an ion implantation process to form the buried channel region under the first impurity region.

The buried channel region may be adjacent to the photo diode.

Forming the first impurity region may include forming a photoresist pattern partially exposing a channel region of the substrate on which the transfer gate is formed, and performing an ion implantation process to form the first impurity region at or in a surface portion of the substrate exposed by the photoresist pattern.

The first impurity region may be adjacent to the photo diode.

### BRIEF DESCRIPTION OF THE DRAWINGS

Exemplary embodiments can be understood in more detail from the following description taken in conjunction with the accompanying drawings, in which:

FIG. 1 is a cross-sectional view of an exemplary CMOS image sensor in accordance with one or more embodiments of the present invention;

FIGS. 2 to 7 are cross-sectional views illustrating an exemplary method of manufacturing the CMOS image sensor shown in FIG. 1;

FIG. 8 is a cross-sectional view of an exemplary buried channel region in accordance with one or more other embodiments of the present invention;

FIG. 9 is a cross-sectional view of an exemplary first impurity region in accordance with one or more further embodiments of the present invention;

FIG. 10 is a block diagram illustrating an exemplary operation of the CMOS image sensor shown in FIG. 1; and

FIG. 11 is a block diagram illustrating an exemplary processor based system including the CMOS image sensor shown in FIG. 1.

### DETAILED DESCRIPTION OF EMBODIMENTS

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when a structure such as a layer, a film, a region or a plate is referred to as being ‘on’ another structure, it can be directly on the other structure, or one or more intervening layers, films, regions, plates or other structures may also be present. Unlike this, it will also be understood that when a structure such as a layer, a film, a region or a plate is referred to as being ‘directly on’ another structure, it is directly on the other one, and one or more intervening layers, films, regions, plates or other structures do not exist therebetween. Also, though terms like “a first,” “a second,” “a third,” etc., are used to describe various components, compositions, regions and/or layers in various embodiments, the present invention are not limited to these terms.

In the following description, the technical terms are used only for explaining specific embodiments while not limiting the present invention. Unless otherwise defined herein, all the terms used herein, which include technical or scientific terms, may have the same meaning that is generally understood by those skilled in the art.

Embodiments of the present invention are described with reference to schematic diagrams of idealized embodiments. Accordingly, changes in the shapes of structures in the diagrams or figures, for example, changes in manufacturing techniques and/or allowable errors, may be expected. Accordingly, embodiments of the present invention are not limited to specific shapes, structures or areas shown in the diagrams or figures, and include deviations in the shapes, structures and areas. The drawings may be entirely schematic, and the shapes therein may not be accurate and do not limit the scope of the present invention.

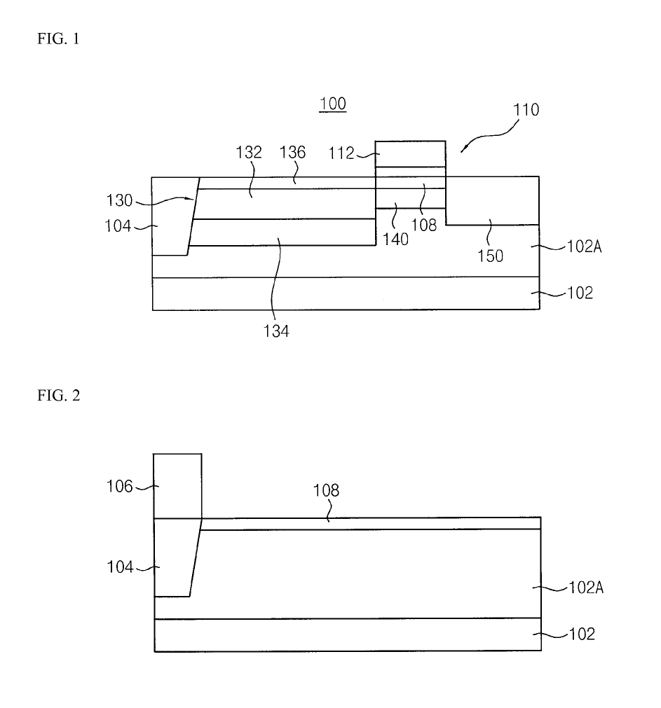

FIG. 1 is a cross-sectional view of an exemplary CMOS image sensor in accordance with one or more embodiments of the present invention.

Referring to FIG. 1, according to exemplary embodiments of the present invention, a CMOS image sensor 100 may include a plurality of photo diodes 130 for detecting light and a plurality of transistors electrically connected to the photo diodes 130.

Especially, the CMOS image sensor 100 may include a plurality of pixels arranged in a plurality of rows and a plurality of columns, and each pixel may include a photo diode 130 and a transfer transistor 110 connected to the photo diode 130.

The pixels may be electrically isolated from each other by device isolation region 104, and a first conductive type, for example, a p-type silicon epitaxial layer 102A, may be formed on a substrate 102.

The photo diode 130 may be formed at or in a surface portion of the substrate 102, and the transfer transistor 110 may include a transfer gate 112 formed on the substrate 102. The photo diode 130 may be formed at or in a surface portion of the substrate 102 on one side of the transfer gate 112, and a floating diffusion region 150 FD may be formed at or in a surface portion of the substrate 102 on another (e.g., an opposite) side of the transfer gate 112. Additionally, although not shown in the drawing, the pixels may further include a reset transistor and a drive transistor connected to the floating diffusion region 150, and a select transistor connected to the drive transistor. Such unit pixel circuitry is known in the art.

A gate oxide layer may be between the substrate 102 and the transfer gate 112, and the transfer gate 112 may comprise doped polysilicon and/or a metal silicide. Additionally, the transfer gate 112 may include spacers that comprise one or more insulating materials (e.g., silicon dioxide and/or silicon nitride), and a capping layer (e.g., of silicon dioxide) may be on the transfer gate 112.

A first impurity region 108 having a first conductive type may be formed at or in a channel region under the transfer gate 112, that is, a surface portion of the substrate 102 between the photo diode 130 and the floating diffusion region 150, and a buried channel region 140 having a second conductive type may be formed under the first impurity region 108. For example, the first impurity region 108 may be a p− impurity region and the buried channel region 140 may be an n− impurity region.

The buried channel region 140 may be uniform across the entire channel region of the transfer transistor 110, and accordingly, the first impurity region 108 and the buried channel region 140 may have the same length or substantially the same length between the photo diode 130 and the floating diffusion region 150.

The first impurity region 108 may be used to reduce signal noise and dark current and to adjust a threshold voltage of the transfer transistor 110. The buried channel region 140 may be used as an anti-blooming channel implant and/or structure, and may be used to reduce crosstalk and image lag phenomena. The first impurity region 108 and the buried channel region 140 will be described in more detail.

The photo diode 130 may include a second impurity region 132 having a second conductive type, formed at or in a surface portion of the substrate 102 on one side of the transfer gate 112, a third impurity region 134 having a second conductive type may be formed under the second impurity region 132, and a fourth impurity region 136 having a first conductive type may be formed on the second impurity region 132.

The third impurity region 134 may have a lower concentration than the second impurity region 132 and may be used to improve the sensitivity of the photo diode 130 to red light having a relatively long wavelength. For example, the second impurity region 132 may be an n+ impurity region, and the third impurity region 134 may be an n− impurity region. Additionally, the fourth impurity region 136 may be a p+ impurity region.

Moreover, the floating diffusion region 150 may have a second conductive type and may be, for example, an n+ impurity region. Although not shown in the drawing, the reset transistor may include the floating diffusion region 150, a reset gate (not shown), and an n+ impurity region (not shown) formed in the substrate on an opposite side of the reset gate from the floating diffusion region 150.

Additionally, although not shown in the drawing, the CMOS image sensor 100 may include signal lines connected to the transistors, insulating layers (e.g., interlayer insulating layers) between the signal lines and/or layers of the signal lines (e.g., metallization), a color filter layer, and micro lenses.

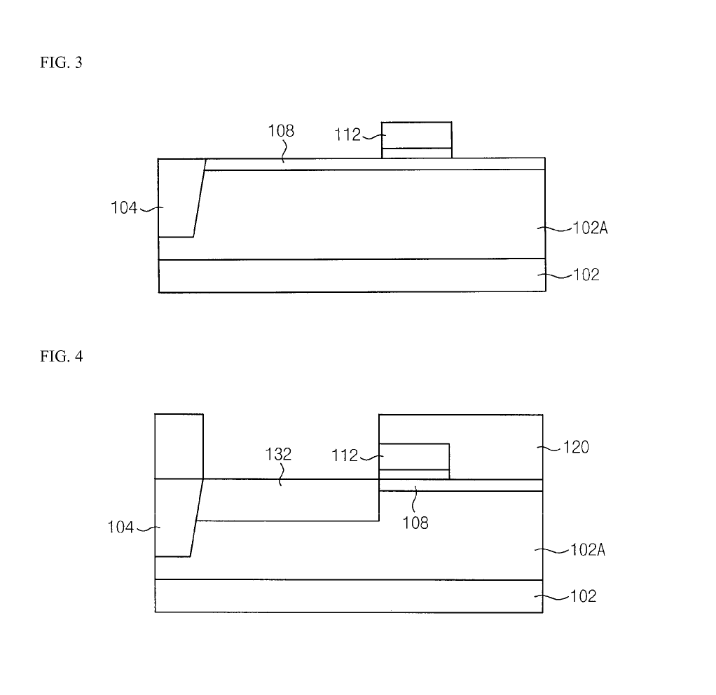

FIGS. 2 to 7 are cross-sectional views illustrating an exemplary method of manufacturing the CMOS image sensor shown in FIG. 1.

Referring to FIG. 2, a substrate 102 on which a first conductive type (for example, p-type) epitaxial layer 102A is formed may be prepared. Alternatively, a first conductive type (for example, a p-type) substrate may be provided without the epitaxial layer 102A. Device isolation regions 104 may be formed at or in surface portions of the epitaxial layer 102A and/or the substrate 102. The device isolation regions 104 may isolate different pixel regions from each other. For example, the device isolation regions 104 may be formed by forming trenches (not shown) at or in surface portions of the epitaxial layer 102A and/or the substrate 102 (e.g., surface portions of the p-type epitaxial layer 102A) using a photolithographic process and an etching process, and filling the trenches with an insulating material (for example, a high density plasma [HDP] oxide, such as undoped silicon dioxide).

Then, a first impurity region 108 having the first conductive type may be formed at or in a surface portion of the substrate 102. In more detail, a first photoresist pattern 106 exposing the pixel regions electrically isolated by the device isolation regions 104 is formed on the substrate 102, and the first impurity region 108 may then be formed by an ion implantation process using a dopant ion having the first conductive type. For example, by implanting a p-type dopant ion (for example, boron or indium) into the pixel regions, the first impurity region 108 may be formed.

The first impurity region 108 may adjust a threshold voltage of the transfer transistor 110 (e.g., in a channel region under the transfer gate 112) and may reduce noise and prevent dark current in a photo diode region on one side of the transfer gate 112. Moreover, the first photoresist pattern 106 may be removed by an ashing and/or stripping process after the first impurity region 108 is formed.

Referring to FIG. 3, after the first impurity region 108 is formed, the transfer gate 112 may be formed on the epitaxial layer 102A and/or the substrate 102 in the pixel region. For example, by forming a gate insulating layer, a gate conductive layer, and a gate capping layer on the substrate 102 or the epitaxial layer 102A and patterning the gate capping layer, the gate conductive layer, and the gate insulating layer, the transfer gate 112 may be formed on the substrate 102 or the epitaxial layer 102A.

Moreover, when forming the transfer gate 112, a reset gate, a drive gate, and a select gate may also be formed simultaneously on the epitaxial layer 102A and/or the substrate 102 in the pixel region.

Referring to FIG. 4, a second photoresist pattern 120 exposing the photo diode region may be formed, and a second impurity region 132 may then be formed at or in a surface portion of the photo diode region by performing an ion implantation process using a dopant ion having a second conductive type (e.g., an n-type). For example, by implanting an n-type dopant ion (for example, arsenic or phosphorus) into the photo diode region, the second impurity region 132 may be formed. The concentration or dose of the n-type dopant ion implanted into the second impurity region 132 is greater than the concentration or dose of the p-type dopant ion implanted into the first impurity region 108.

The second photoresist pattern 120 may be removed through an ashing and/or stripping process after the second impurity region 132 is formed.

Referring to FIG. 5, a third photoresist pattern 122 exposing the transfer gate 112 and the photo diode region may be formed. Then, by performing an ion implantation process using a dopant ion having the second conductive type, a third impurity region 134 may be formed under the second impurity region 132, and further, a buried channel region 140 may be formed under the first impurity region 108.

For example, by implanting an n-type dopant ion (for example, arsenic or phosphorus) into the photo diode region and the channel region, the third impurity region 134 and the buried channel region 140 may be formed. The ion implantation process may be performed by energy of about 100 KeV to about 5 MeV or more preferably may be performed by energy of about 400 KeV to about 1 MeV. The concentration or dose of the n-type dopant ion implanted into the third impurity region 134 and the buried channel region 140 is less than the concentration or dose of the n-type dopant ion implanted into the second impurity region 132 and less than the concentration or dose of the p-type dopant ion implanted into the first impurity region 108.

The third photoresist pattern 122 may be removed through an ashing and/or stripping process after the third impurity region 134 and the buried channel region 140 are formed.

Referring to FIG. 6, a fourth photoresist pattern 124 exposing the photo diode region may be formed, and a fourth impurity region 136 may then be formed on or in the second impurity region 132 by performing an ion implantation process using a dopant ion having the first conductive type. For example, by implanting a p-type dopant ion (for example, boron or indium) into the photo diode region, the fourth impurity region 136 may be formed and accordingly, a pinned photo diode 130 may be formed. The concentration or dose of the p-type dopant ion implanted into the fourth impurity region 136 is greater than the sum of the concentrations or doses of the n-type dopant ion implanted into the second impurity region 132 and third impurity region 134.

The fourth photoresist pattern 124 may be removed through an ashing and/or stripping process after the second impurity region 136 is formed.

Referring to FIG. 7, after the photo diode 130 is formed, a second conductive type impurity region functioning as the floating diffusion region 150 may be formed on another (e.g., opposite) side of the transfer gate 112 by an ion implantation process. For example, a fifth photoresist pattern 126 exposing the floating diffusion region 150 may be formed, and an n-type dopant ion (for example, arsenic or phosphorus) may then be implanted into the floating diffusion region 150. The concentration or dose of the n-type dopant ion implanted into the floating diffusion region 150 is much greater than the concentration or dose of the p-type dopant ion implanted into the first impurity region 108.

The fifth photoresist pattern 126 may be removed through an ashing and/or stripping process after the floating diffusion region 150 is formed.

As a result, the transfer transistor 110 including the transfer gate 112, the photo diode 130, and the floating diffusion region 150 may be formed in the pixel region. Moreover, when forming the floating diffusion region 150, source/drain regions of the reset transistor, the drive transistor, and the select transistor may also be formed simultaneously.

Moreover, each of the gates 112 (e.g., of the transfer, reset, drive, and select transistors) may include spacers (not shown). The spacers may comprise a silicon oxide (e.g., SiO₂) and/or a silicon nitride (e.g., Si₃N₄) and may be formed before or after forming the photo diode 130 and the floating diffusion region 150. In one embodiment, the spacers are formed before forming the photo diode 130 and the floating diffusion region 150.

According to exemplary embodiments of the present invention, the buried channel region 140 is between the photo diode 130 and the floating diffusion region 150 (e.g., entirely or substantially entirely), and the buried channel region 140 may reduce an electrical resistance of the channel region of the transfer transistor. Accordingly, charge transfer efficiency may be improved in the channel region and/or the transfer transistor, and also, remaining charge or charge carriers may be greatly reduced in the photo diode 130.

As a result, a dynamic range of the photo diode 130 may be improved and charge or charge carriers generated in the photo diode 130 may sufficiently transfer to the floating diffusion region 150 through the buried channel region 140. That is, the buried channel region 140 may function as an “anti-blooming” channel and accordingly, the blooming phenomenon, in which excess charges overflow from the photo diode 130 into adjacent pixel regions, may be reduced.

Further, charge leakage from the photo diode 130 to adjacent or other pixels may be reduced greatly, and accordingly, crosstalk in or from the CMOS image sensor 100 may be reduced greatly. Still further, an image lag phenomenon generated by the charge or charge carriers remaining in the photo diode 130 after transfer to the floating diffusion region 150 may be reduced.

Moreover, although not shown in the drawing, after the floating diffusion region 150 is formed, a first insulating layer may be formed on the substrate 102 or the epitaxial layer 102A (and the gates of the transfer, reset, drive, and select transistors), and signal lines may be formed on the first insulating layer and connected to the transistors. The signal lines may be connected to the transistors through contact plugs in the first insulating layer.

Additionally, a plurality of insulating layers (e.g., interlayer insulating layers) and at least one wiring layer on each of the insulating layers (other than the uppermost insulating layer) may be formed on or over the signal lines. A protective layer and a color filter layer may be formed on the uppermost insulating layer, and a planarization layer and a plurality of micro lenses may be formed on the color filter layer.

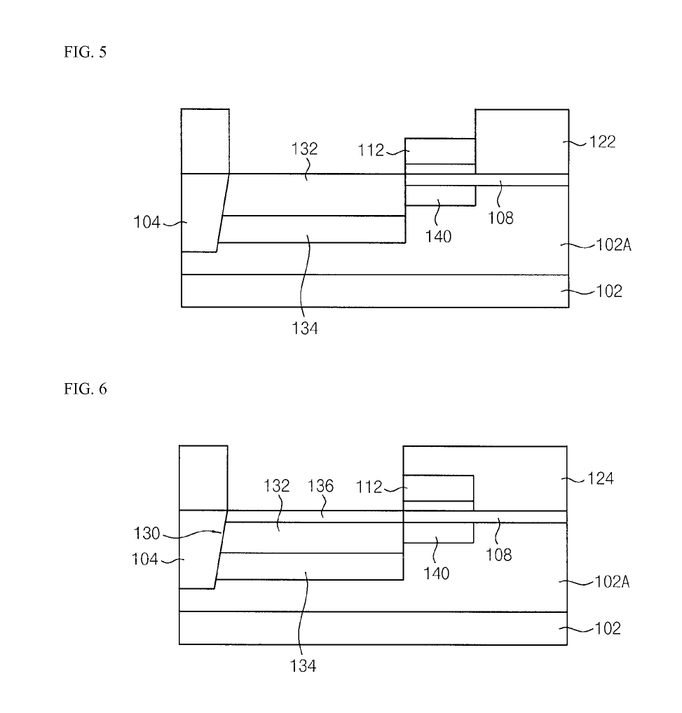

FIG. 8 is a cross-sectional view of an exemplary buried channel region in accordance with one or more other exemplary embodiments.

Referring to FIG. 8, a buried channel region 140A may be formed under the first impurity region 108. The buried channel region 140A may be formed together with the third impurity region 134 and may have a shorter length (e.g., distance across the channel under the transfer gate 112) than the first impurity region 108. Particularly, the buried channel region 140A may have a shorter length than the channel region and may be formed adjacent to the photo diode 130.

The buried channel region 140A may be formed by forming a photoresist pattern (not shown) partially exposing the transfer gate 112 (e.g., of the same side as the photo diode 130) and then performing an ion implantation process using a second conductive type dopant ion (for example, an n-type dopant ion such as arsenic or phosphorus).

Compared to the buried channel region 140 shown in FIG. 1, the buried channel region 140A having a shorter length than the channel region may increase a threshold voltage of the transfer transistor 110 and/or reduce dark current and/or noise (e.g., relative to an otherwise identical transistor having a buried channel region 140 with the same length as the channel region). Accordingly, the CMOS image sensor 100A including the buried channel region 140A may be used in a relatively dark environment.

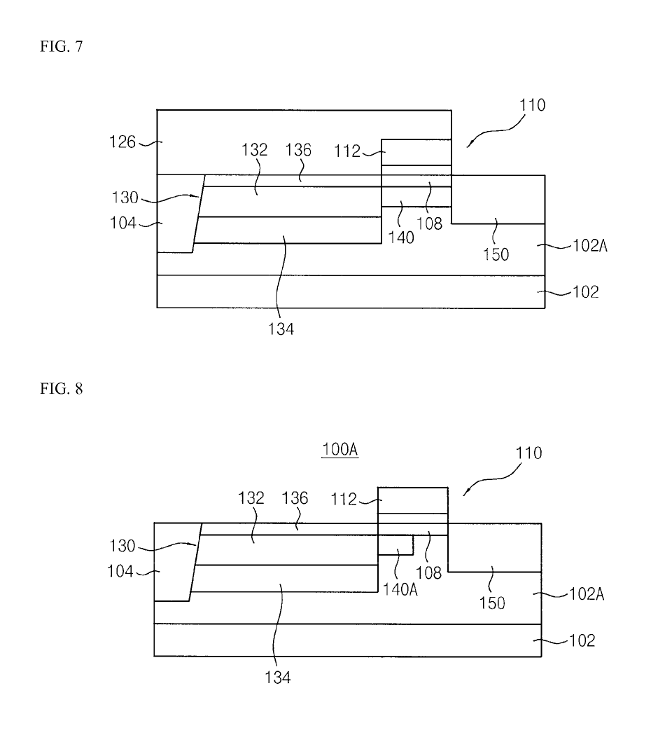

FIG. 9 is a schematic or cross-sectional view of a first impurity region in accordance with one or more further exemplary embodiments of the present invention.

Referring to FIG. 9, a first impurity region 108A may be partially formed at or in a surface portion of the channel region under the transfer gate 112. Particularly, the first impurity region 108A may be formed adjacent to the photo diode 130 and in this case, a buried channel region 140B may be formed entirely or substantially entirely under the first impurity region 108A and the transfer gate 112. That is, the first impurity region 108A may have a shorter length than the buried channel region 140B.

The first impurity region 108A may be formed by forming a photoresist pattern (not shown) partially exposing the channel region and then performing an ion implantation process using a first conductive type dopant ion (for example, a p-type dopant ion such as boron or indium).

Accordingly, the channel length and threshold voltage of the transfer transistor 110 including the first impurity region 108A may be reduced. As a result, the CMOS image sensor 100B including the first impurity region 108A may reduce a blooming phenomenon and an image lag phenomenon. Especially, the CMOS image sensor 100B may be used in a relatively bright environment.

Moreover, the above-mentioned CMOS image sensor 100 may include a logic region connected to the pixel regions.

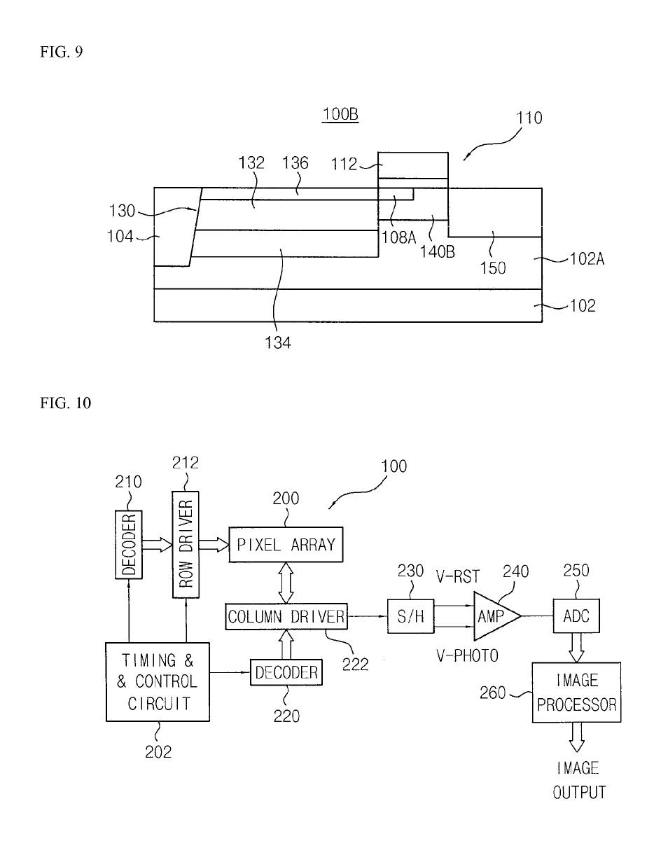

FIG. 10 is a block diagram illustrating exemplary circuit blocks and/or operations of the CMOS image sensor shown in FIG. 1.

Referring to FIG. 10, the CMOS image sensor 100 may include a plurality of pixel regions in the pixel array 200. The pixel regions may be arranged in a predetermined number of columns and rows.

Rows of pixel regions in a pixel array 200 may be read out one by one. Accordingly, pixels in a row of the pixel array 200 may be selected to be read out simultaneously, and also signals indicating light received from the selected pixels may be selectively read out by a column select line.

A row line in the pixel array 200 may be selectively activated by a row address decoder 210 and a row driver 212. A column select line may be selectively activated by a column address decoder 220 and a column driver 222. The pixel array 200 is operated by the timing and control circuit 202, which controls the address decoders 210 and 220 and optionally the row and column drivers 212 and 222 in order to select a (proper) row and column and read out the corresponding pixel signal(s).

The signals on the column read-out lines typically include a pixel reset signal V-rst and a pixel image signal V-photo for each pixel. Both signals are read into a sample and hold circuit (S/H) 230 in response to the column driver 222. A differential signal Vrst-Vphoto for each pixel is produced by a differential amplifier (AMP) 240 and each pixel's differential signal is digitized by an analog to digital converter (ADC) 250. The analog to digital converter 250 supplies the digitized pixel signals to an image processor 260, and then the image processor 260 processes the digitized pixel signals and provides one or more digital signals defining an image output.

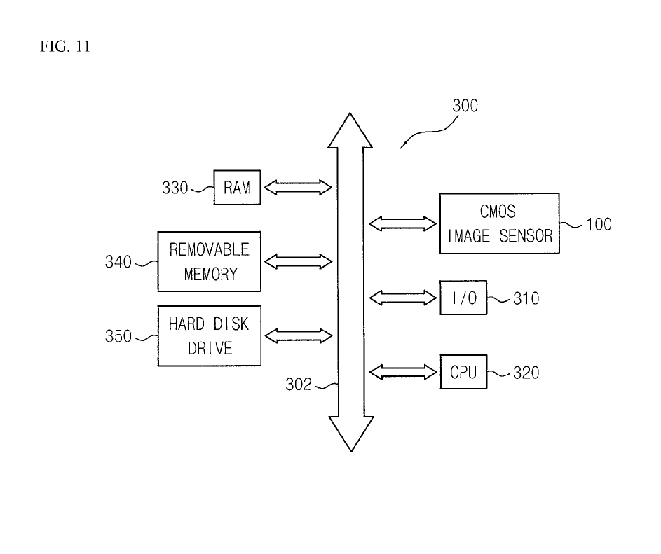

FIG. 11 is a block diagram illustrating an exemplary processor based system including the CMOS image sensor of FIG. 1.

Referring to FIG. 11, the processor based system 300 may include a digital circuit including the CMOS image sensor 100. For example, the processor based system 300 may include a computer system, a camera system, a scanner, a machine vision system or device, a vehicle navigation system or device, a video phone, a surveillance system, an auto focus system, a star tracker system, a motion detection system, and/or a system that requires image acquisition.

The processor based system 300 (for example, a camera system) typically includes a central processing unit (CPU) 320 such as a microprocessor communicating with an input/output (I/O) device 310 over a bus 302. The CMOS image sensor 100 communicates with the CPU 320 over the bus 302. The processor based system 300 includes a random access memory (RAM) 330, and also may include a removable memory 340 (such as flash memory) and a hard disk drive 350 communicating with the CPU 320 over the bus 302.

According to the above-mentioned embodiments of the present invention, the transfer gate 112 may be formed on or over the channel region between the photo diode 130 and the floating diffusion region 150, and the first impurity region 108 having the first conductive type may be formed at or in the surface portion of the channel region. The buried channel region 140 having the second conductive type may be formed under the first impurity region 108 and may form or be a charge transfer path between the photo diode 130 and the floating diffusion region 150.

Particularly, the buried channel region 140 may reduce an electrical resistance of the channel region, and accordingly, may reduce charge or charge carriers remaining in the photo diode 130 after transfer to the floating diffusion region 150. As a result, the blooming and image lag phenomena of the CMOS image sensor 100 including the buried channel region 140 may be reduced.

Further, the photo diode 130 may include the second impurity region 132 having the second conductive type, the third impurity region 134 having the second conductive type under the second impurity region 132, and the fourth impurity region 136 having the first conductive type formed on or in the second impurity region 132. The third impurity region 134 may improve the sensitivity to red light and may also improve the dynamic range of the CMOS image sensor 100.

Still further, since the buried channel region 140 may be formed simultaneously with the third impurity region 134, the manufacturing process of the CMOS image sensor 100 including the buried channel region 140 may be simplified.

Although the CMOS image sensor and the method of manufacturing the same have been described with reference to specific embodiments, they are not limited thereto. Therefore, it will be readily understood by those skilled in the art that various modifications and changes can be made thereto without departing from the spirit and scope of the present invention defined by the appended claims.

What is claimed is:

1. A complementary metal-oxide-semiconductor (CMOS) image sensor comprising:
a transfer gate on a substrate;
a photo diode at or in a surface portion of the substrate on one side of the transfer gate;
a floating diffusion region at or in a surface portion of the substrate on another side of the transfer gate;
a first impurity region having a first conductive type at or in a surface portion of the substrate between the photo diode and the floating diffusion region; and
a buried channel region having a second conductive type under the first impurity region.

2. The CMOS image sensor of claim 1, wherein the photo diode comprises:
a second impurity region having the second conductive type at or in the surface portion of the substrate;
a third impurity region having the second conductive type under the second impurity region; and
a fourth impurity region having the first conductive type on the second impurity region.

3. The CMOS image sensor of claim 2, wherein the third impurity region has a lower impurity concentration than the second impurity region.

4. The CMOS image sensor of claim 1, wherein the substrate has the first conductive type.

5. The CMOS image sensor of claim 1, wherein the buried channel region has a same length as the first impurity region.

6. The CMOS image sensor of claim 1, wherein the buried channel region has a shorter length than the first impurity region.

7. The CMOS image sensor of claim 1, wherein the first impurity region has a shorter length than the buried channel region.

8. A method of manufacturing a complementary metal-oxide-semiconductor (CMOS) image sensor, the method comprising:
forming a first impurity region having a first conductive type at or in a surface portion of a substrate;
forming a transfer gate on the first impurity region;
forming a photo diode at or in a surface portion of the substrate on one side of the transfer gate;
forming a buried channel region having a second conductive type under the first impurity region; and
forming a floating diffusion region at or in a surface portion of the substrate on another side of the transfer gate.

9. The method of claim 8, wherein the forming of the photo diode comprises:
forming a second impurity region having the second conductive type at the surface portion of the substrate;
forming a third impurity region having the second conductive type under the second impurity region; and
forming a fourth impurity region having the first conductive type on the second impurity region.

10. The method of claim 9, wherein the buried channel region is formed simultaneously with the third impurity region.

11. The method of claim 9, wherein the third impurity region has a lower impurity concentration than the second impurity region.

12. The method of claim 8, wherein the substrate has the first conductive type.

13. The method of claim 8, wherein forming the buried channel region comprises:
forming a photoresist pattern exposing the transfer gate; and
performing an ion implantation process to form the buried channel region under the first impurity region.

14. The method of claim 13, wherein the ion implantation process is performed using an energy of about 400 KeV to about 1 MeV.

15. The method of claim 8, wherein forming the buried channel region comprises:
forming a photoresist pattern partially exposing the transfer gate; and
performing an ion implantation process to form the buried channel region under the first impurity region.

16. The method of claim 15, wherein the buried channel region is adjacent to the photo diode.

17. The method of claim 8, wherein forming the first impurity region comprises:
forming a photoresist pattern partially exposing a channel region of the substrate on which the transfer gate is formed; and
performing an ion implantation process to form the first impurity region at or in a surface portion of the substrate exposed by the photoresist pattern.

18. The method of claim 17, wherein the first impurity region is adjacent to the photo diode.
